(19) United States
(12) Patent Application Publication
(10) Pub. No.: US 2006/0076569 A1
(43) Pub. Date: Apr. 13, 2006

(54) Semiconductor light emitting device

(75) Inventors: Kazuaki Otsuka, Kanagawa-ken (JP); Hatsuo Takezawa, Kanagawa-ken (JP); Masaaki Tamatani, Kanagawa-ken (JP)

Correspondence Address: BANNER & WITCOFF, LTD., ATTORNEYS FOR RESERVE;CLIENT NO. 4, 1001 G STREET, N.W., 11TH FLOOR, WASHINGTON, DC, 20001-4597, US

(73) Assignee: Kabushiki Kaisha Toshiba, Tokyo (JP)

(21) Appl. No.: 11/249,134

(22) Filed: Oct. 13, 2005

(30) Foreign Application Priority Data
Oct. 13, 2004 (JP) 2004-299421

(51) Int. Cl. H01L 33/00

(52) U.S. Cl. 257/98; 257/100

(57) ABSTRACT

In one aspect of the present invention, a semiconductor light emitting device may include a light emitting element configured to emit a first wavelength light and a phosphor configured to absorb the first wavelength light and emit light of a second wavelength which is different from the first wavelength. The phosphor contains a silicate represented by the formula (Me_{1-y}Eu_{y})₂SiO₄, wherein Me is at least one element selected from the group consisting of Ba, Sr, Ca and Mg, and y is >0. The phosphor has a grain size of from about 10 to about 50 micrometers.

### CROSS REFERENCE TO RELATED APPLICATION

This application is based upon and claims the benefit of priority from Japanese Patent Application No. 2004-299421, filed on Oct. 13, 2004, the entire contents of which are incorporated herein by reference.

### BACKGROUND OF THE INVENTION

Semiconductor light emitting devices have become widely used in various settings such as general lightings and displays. Semiconductor light emitting devices which emit white light are particularly desirable for various purposes.

A white light emitting device typically has a light emitting element (LED) which emits short wavelength light and a phosphor which converts the light to a different wavelength. Light of a predetermined optical spectrum can be obtained by mixing different kinds of phosphors. Certain characteristics of the emitted light can be controlled by varying the distribution of the phosphors.

One example of a white light emitting device has a blue light LED and a yellow phosphor. The white light is obtained by mixing the blue light from the LED and a yellow light converted by the yellow phosphor.

Another example of a white light emitting device has an ultraviolet light LED and three kinds of phosphors, such as blue, green, and red phosphors.

### SUMMARY OF THE INVENTION

In one aspect of the present invention, a semiconductor light emitting device may include a light emitting element configured to emit a first wavelength light and a phosphor configured to absorb the first wavelength light and emit light of a second wavelength which is different from the first wavelength. The phosphor contains a silicate represented by the formula (Me_{1-y}Eu_{y})₂SiO₄, wherein Me is at least one element selected from the group consisting of Ba, Sr, Ca and Mg, and y is >0. The phosphor has a grain size of from about 10 to about 50 micrometers.

In another aspect of the present invention, a semiconductor light emitting device may include a light emitting element configured to emit a first wavelength light and a phosphor configured to absorb the first wavelength light and emit light of a second wavelength which is different from the first wavelength. The phosphor contains a silicate represented by the formula (Me_{1-y}Eu_{y})₂SiO₄, wherein Me is at least one element selected from the group consisting of Ba, Sr, Ca and Mg, and y is >0. The phosphor has a grain size of from about 10 to about 50 micrometers. A particle is provided on the phosphor, wherein the particle has a grain size which is less than the grain size of the phosphor.

In another aspect of the present invention, a semiconductor light emitting device may include a light emitting element configured to emit a first wavelength light and a first phosphor configured to absorb the first wavelength light and emit light of a second wavelength which is different from the first wavelength. The first phosphor contains a silicate represented by the formula (Me_{1-y}Eu_{y})₂SiO₄, wherein Me is at least one element selected from the group consisting of Ba, Sr, Ca and Mg, and y is >0. The first phosphor has a grain size of from about 10 to about 50 micrometers. A second phosphor is configured to absorb the first wavelength light and emit light of a third wavelength which is different from the first wavelength and from the second wavelength.

### BRIEF DESCRIPTIONS OF THE DRAWINGS

The present invention will now be described in more detail with reference to embodiments of the invention, given only by way of example, and illustrated in the accompanying drawings in which:

FIG. 1 is a cross sectional view of a semiconductor light emitting device in accordance with a first embodiment of the present invention;

FIG. 2 is a graph illustrating a distribution of a particle size of phosphors classified by a mesh;

FIG. 3 is a graph illustrating a light intensity of classified yellow phosphors;

FIG. 4A and FIG. 4B are schematic cross sectional views of phosphors;

FIG. 5 is a cross sectional view of a semiconductor light emitting device in accordance with a second embodiment of the present invention;

FIG. 6 is a schematic view of a phosphor with fine powder;

FIG. 7 is a flow chart showing a manufacturing process of a phosphor with fine powder;

FIG. 8 is a cross sectional view of a semiconductor light emitting device in accordance with a third embodiment of the present invention;

FIG. 9 is a schematic view of a combined phosphor; and

FIG. 10 is a flow chart showing a manufacturing process of a combined phosphor.

### DETAILED DESCRIPTION OF THE INVENTION

Various connections between elements are hereinafter described. It is noted that these connections are illustrated in general and, unless specified otherwise, may be direct or indirect and that this specification is not intended to be limiting in this respect.

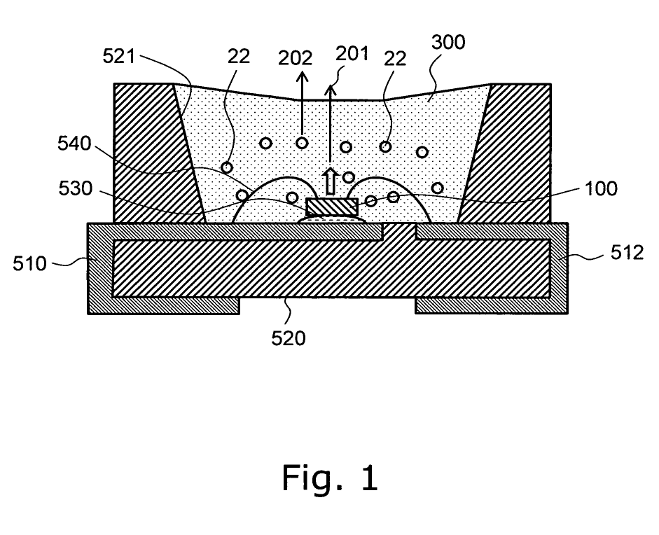

FIG. 1 is a cross sectional view of a semiconductor light emitting device in accordance with a first embodiment of the present invention. In this embodiment, a semiconductor light emitting device is a SMD (Surface Mount Device) suitable to be mounted on a circuit board.

As shown in FIG. 1, a light emitting element (LED chip) 100 is mounted on a first lead 510 with an adhesive 530. A first electrode of the LED chip 100 which is provided on a top surface of the LED chip 100 is electrically connected to the first lead 510 with a bonding wire 540. A second electrode of the LED chip 100 which is provided on a bottom surface of the LED chip 100 is electrically connected to a second lead 512 with a bonding wire 540. The leads 510, 512 can be embedded with a thermoplastic resin 520 by injection molding.

Alternatively a reflection material may be mixed into the thermoplastic resin 520, e.g., to improve the reflection ratio of the resin.

The LED chip 100 may be GaN based semiconductor. A GaN based semiconductor light emitting element is capable of emitting a light about 300 nm to 540 nm (ultraviolet/blue/green light) corresponding to its composition. In this embodiment, the LED chip 100 emits blue light whose wavelength is about 460 nm.

The LED chip 100 can be molded with a transparent resin 300. A yellow phosphor 22 is dispersed in the transparent resin 300. A portion of the blue light 201 emitted from the LED chip 100 is absorbed by the yellow phosphor 22, which converts the blue light 201 to yellow light 202. The blue light 201 and yellow light 202 are combined so that the resulting light emitted appears white to the human eye.

The yellow phosphor 22 is explained hereinafter.

In this embodiment, the yellow phosphor 22 contains a silicate represented by the formula (Me_{1-y}Eu_{y})₂SiO₄, wherein Me is at least one of Ba, Sr, Ca and Mg. The phosphor may contain additional components, such as one or more alkaline earth metal phosphates, alkaline earth metal aluminates, alkaline earth metal borates and alkaline earth metal germinates.

The characteristic of the phosphor is explained next with reference to its manufacturing process.

A composition of SrCO₃, BaCO₃, SiO₂, EuCO₃ and NH₄Cl is mixed at a ratio (w/w) of approximately 52:4:13:2.5:1.

The composition is calcined in a predetermined atmosphere such as an air, an inert gas, a vacuum and a reduction atmosphere. A temperature of calcination and a time of calcination can be selected so as to form a single crystal phosphor or a substantially single crystal phosphor. An example of suitable temperature and time conditions are 900-1300° C. and 1-10 hours.

The phosphor is smashed into fine by a beads or a wet milling and classified with a range of the grain size by passing through a mesh. A grain (or particle) of the phosphor above mentioned process is made of a substantially single crystal phase. In other words, the grain of the phosphor is made of a single crystal or a polycrystal which has a relatively small number of crystals.

In this embodiment, grain size is determined based on a mesh aperture for classification. For example, a particle which does not pass through a mesh having a 10×10 micrometer aperture is considered to have a particle size of about 10 micrometers or more. A particle which passes through a mesh having a 50×50 micrometer aperture is considered to have a particle size of about 50 micrometers or less. A particle which meets both of these criteria thus has a particle size from about 10 to about 50 micrometers.

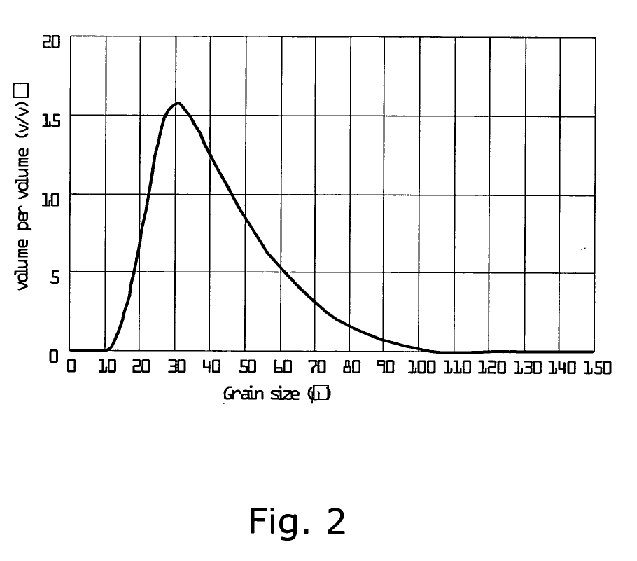

FIG. 2 is a graph illustrating a distribution of a particle size classified by mesh. In FIG. 2, the horizontal axis shows phosphor grain size and the vertical axis shows the corresponding volume per total phosphor volume. The graph shown in FIG. 2 represents a phosphor which passes through a mesh having a 75×75 micrometer aperture and which is left on a mesh having a 20×20 micrometer aperture.

As shown in FIG. 2, up to about 5% (v/v) of phosphor particles having a grain size of 20 micrometers or less are blended after the above-mentioned classification. At the upper end of the range, up to about 2% (v/v) of phosphor particles having a grain size of 75 micrometers or more are blended. Therefore, a phosphor of this classification can be said to contain particles of which at least about 95% (v/v) have a particle size of least about 20 micrometers and of which at least about 98% (v/v) have a particle size of about 75 micrometers or less. More generally, a phosphor having a particle size from X to Y contains particles of which at least about 95% (v/v) have a particle size of least X and of which at least about 98% (v/v) have a particle size of Y or less.

Phosphors can be meshed by a nylon mesh having 5-, 10-, 15-, 20-, and 50-micrometer apertures. A classification of phosphors is operated in the ranges of less than 5 micrometers, 5-10 micrometers, 10-15 micrometers, 15-20 micrometers, 20-50 micrometers, and 50 or more micrometers.

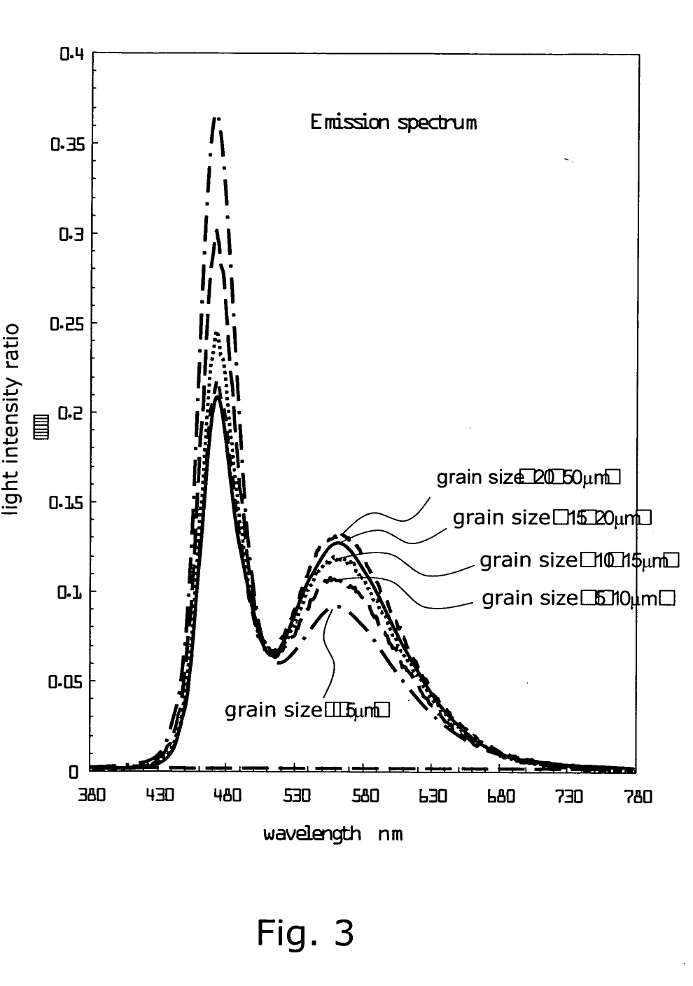

FIG. 3 is a graph illustrating a light intensity of classified yellow phosphors. Spectrum is shown when classified yellow phosphor is set on a dish and irradiated by blue light (460 nm center wavelengths). Emission spectrum (optical spectrum) is obtained. The peak wavelength of the light from the yellow phosphors is provided about 460 nanometers and 580 nanometers. The spectrum about the 460 nanometers is the blue light reflected by the yellow phosphors. The spectrum about the 580 nanometers is yellow light converted by the yellow phosphors.

As shown in FIG. 3, the intensity of the yellow light is increased and the intensity of the blue light is decreased as the grain size of the phosphors is increased. In other words, the phosphor having the grain size of 5 micrometers yielded the least intense yellow light and most intense blue light, followed by the phosphors of grain size 5-10 micrometers, 10-15 micrometers, 15-20 micrometers, and 20-50 micrometers. The phosphor having a grain size of 20-50 micrometers yielded the most intense yellow light and the least intense blue light.

The phosphor having 10-15 micrometers is about 10% better in optical intensity than the phosphor having 5-10 micrometers. The phosphor having 15-20 micrometers is about 19% better in optical intensity than the phosphor having 5-10 micrometers. The phosphor having 20-50 micrometers is about 27% better in optical intensity than the phosphor having 5-10 micrometers.

A grain size of about 10 micrometers or more is preferable for the yellow phosphors containing silicate as described herein. Preferably, the phosphor has a grain size of about 15 micrometers or more, and even more preferably about 20 micrometers or more.

Regarding mass manufacturing process of the phosphors, phosphors having a grain size of about 15 micrometers or more are preferable, as stable light intensity is obtained.

The grain size of phosphors may be changed by controlling the amount of fluxes, the temperature of calcine or the condition of milling during its manufacturing process, as will be apparent to persons skilled in the art.

A greater grain size phosphor in general has a greater intensity of light emission. This is because the light scattering loss is reduced or the ratio in surface area of the broken layer or the metamorphic layer to the whole grain of the phosphor is reduced.

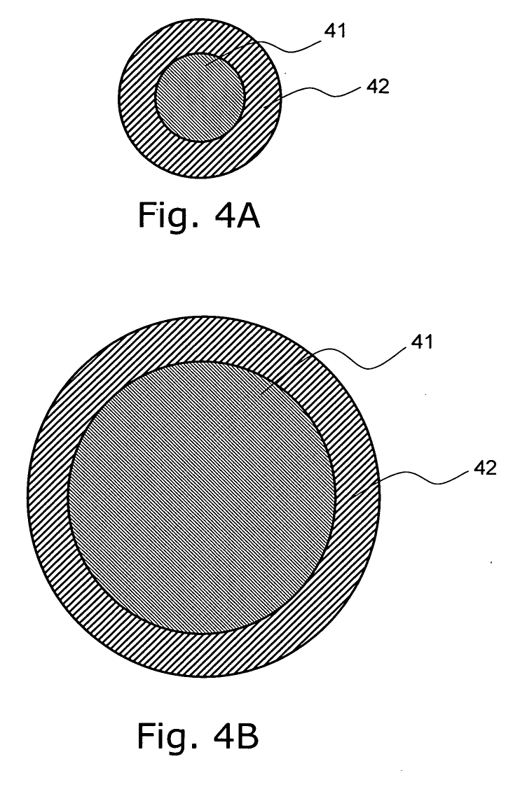

FIG. 4A and FIG. 4B are schematic views illustrating a cross sectional view of phosphor. The grain of the phosphor is not a true sphere. However, the shape of the grain is approximated to a sphere and an approximated diameter of the grain of the phosphor is obtained.

For example, the phosphor made by the manufacturing process may have a damaged layer which is formed on the surface of the grain during smashing the phosphors by milling. A metamorphic layer which is affected by humidity or an ambient atmosphere may be provided on the surface of the grain. Namely, the grain has a structure an active layer 41 covered by an inert layer 42. It may be supposed that the inert layer 42 may have a predetermined thickness almost independent from the size (diameter) of the grain.

As shown in FIG. 4A, where the grain size of the phosphor is smaller, a volume per unit volume of the inert layer 42 is relatively large and the light intensity of the phosphor is reduced. As shown in FIG. 4B, where the grain size is larger, a volume per unit volume of the inert layer 42 is relatively small and the light intensity of the phosphor is increased. That is, light intensity is generally greater when the grain size is larger.

Where the grain size of phosphor is too large, color blurring may occur in which case uniform white light is not obtained. Furthermore, an ejecting hole of a dispenser which is for potting the resin and phosphors may be choked by the phosphor. Because of this, phosphors having a grain size of more than about 50 micrometers are not preferred.

Generally, silicates have low water resistance. However, phosphors with larger grain size generally have smaller metamorphic layers, which can help reduce the effect of the low water resistance.

As mentioned above, the phosphor preferably has a grain size of about 10 micrometers or more, preferably about 15 micrometers or more, and even more preferably about 20 micrometers or more. Larger particle sizes yield improved light intensity. From the standpoint of mass manufacturing, phosphors having a grain size of about 15 micrometers or more are preferred.

A semiconductor light emitting device in accordance with a second embodiment of the present embodiment is explained hereinafter.

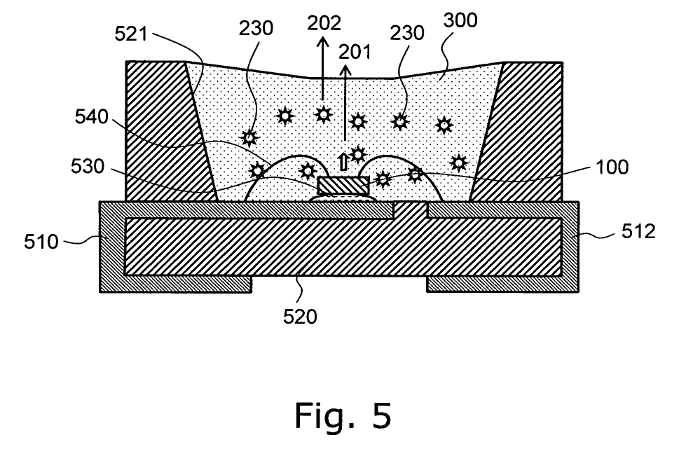

FIG. 5 is a cross sectional view of a semiconductor light emitting device in accordance with a second embodiment of the present invention. With respect to each portion of this second embodiment, the same portions of the semiconductor light emitting device of the first embodiment shown in FIG. 1 to FIG. 4B are designated by the same reference numerals, and its explanation of such portions is omitted.

In this embodiment, a phosphor 230 which has a fine powder on the surface is dispersed in the transparent resin 300.

When the grain size of the phosphor is increased, the weight of the phosphor is also increased. The sedimentation speed of the phosphor dispersed in the transparent resin 300 before curing is increased.

The sedimentation speed depends on such factors as the grain size and the relative density. The sedimentation speed is approximated by the Stokes' law. The sedimentation speed is proportionate to the square of the grain diameter multiplying relative density. In general, greater grain size leads to greater sedimentation speed. The dispersed condition of the phosphors in the transparent resin 300 or a distribution of the phosphor in the transparent resin 300 is changed according to the time for manufacturing process. The variation of chromaticity may occur. The characteristic of light emission may be varied according to manufacturing lot.

In this embodiment, a fine powder 210 is attached on the phosphor 22 so as to reduce the sedimentation speed in the transparent resin.

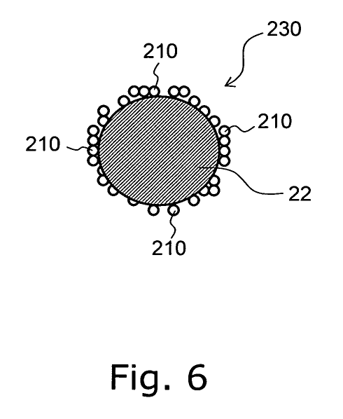

FIG. 6 is a schematic view of a phosphor with fine powder. Fine powder 210 is attached on the surface of the yellow phosphor 22. A variety of materials may be used for the powder, non-limiting examples of which include silica, alumina, alkaline earth metal hydride, and alkaline earth metal oxide. Fine powder 210 may have a good transparency to visible light or ultraviolet light. An affinity with the solvent (liquid resin before curing) can be improved by surface modification (e.g. adding functional group) of the fine powder. Thus, the controllability of the sedimentation speed of the yellow phosphor 22 can be improved. Preferred grain sizes for the fine powder 210 range from about 0.01 to about 0.5 micrometers.

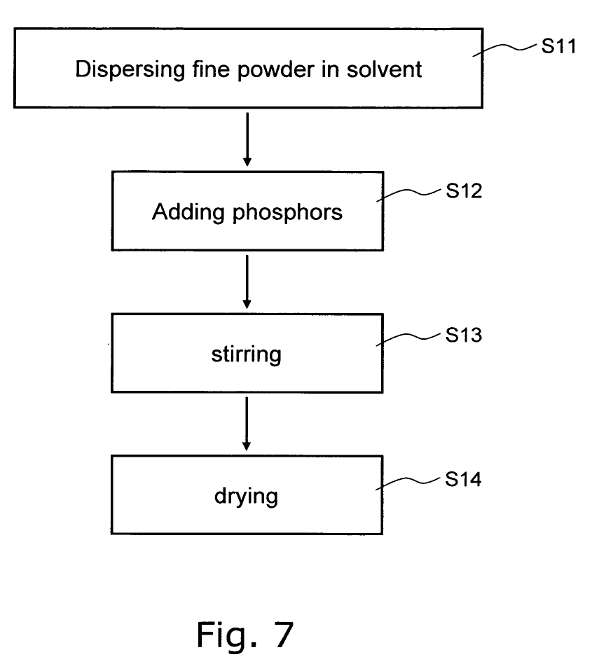

A manufacturing process of the phosphor with a fine powder is next explained. FIG. 7 is a flow chart showing a manufacturing process of a phosphor with fine powder.

In Step S11, a fine powder 210 such as silica, an alumina, an alkaline earth metal hydride or an alkaline earth metal oxide is provided in water or an organic solvent (e.g. alcohol) and dispersed by applying a supersonic wave.

In Step S12, the phosphors 23 are added gradually with stirring.

In Step S13, stirring is performed for a predetermined period. The fine powder is attached on the surface of the phosphors.

In Step S14, the phosphors are dried in an ambient atmosphere such as 100-150° C. Phosphors with fine powder 230 are thus obtained.

An alkaline earth metal hydroxide or oxide may be obtained such as by etching the surface of the phosphors with water or weak acid and hydrolyzing the solvent extracted alkaline earth metal.

The phosphors with fine powder 230 may be mixed to liquid transparent resin 300 (e.g. silicone resin or epoxy resin). The mixed liquid transparent resin 300 can be potted on the LED chip 100 and cured. The LED chip 100 can be molded by the transparent resin 300.

As mentioned above, in this embodiment fine powder is attached to the phosphor. The variation of the optical characteristic (e.g. color chiromancy) among the semiconductor light emitting devices may be reduced.

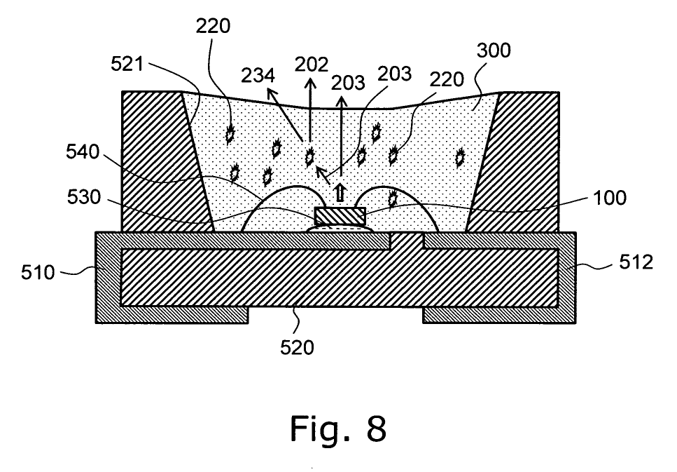

A semiconductor light emitting device in accordance with a third embodiment of the present embodiment is explained hereinafter. FIG. 8 is a cross sectional view of a semiconductor light emitting device in accordance with a third embodiment of the present invention. With respect to each portion of this third embodiment, the same portions of the semiconductor light emitting device of the first embodiment shown in FIG. 1 to FIG. 7 are designated by the same reference numerals, and its explanation of such portions is omitted.

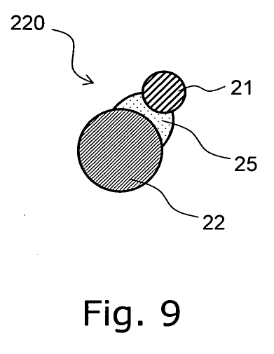

In this embodiment a combined phosphor 220 is dispersed in the transparent resin 300. As shown in FIG. 9, the combined phosphor 220 has a blue phosphor 21 and yellow phosphor 22. The blue phosphor 21 and the yellow phosphor 22 are combined by a binder resin 25. The combined phosphor 220 is mixed in the liquid transparent resin 300 and dispersed in the liquid transparent resin 300.

Ultraviolet light 203 having about 380 nanometers wavelength emitted from the LED chip 100 is absorbed by the blue phosphor 21 and converted in wavelength. Blue light 234 is emitted from the blue phosphor 21.

Ultraviolet light 203 is absorbed by the yellow phosphor 22 and converted in wavelength. Yellow light 202 is emitted from the yellow phosphor 22. Visible white light is obtained by the combined blue light 234 and yellow light 202.

A halophosphate phosphor may be used as the blue phosphor 21. For example, (Me₁₋ₓEuₓ)₁₀(PO₄)₆Cl₂, in which the Me is an element one of Ba, Sr, Ca and Mg, and x>0, may be used as the blue phosphor 21.

A silicate phosphor may be used as the yellow phosphor 22. A phosphor represented by the formula (Me_{1-y}Eu_{y})₂SiO₄ in which the Me is at least one of Ba, Sr, Ca and Mg, and y>0, may be used as the yellow phosphor 22. An alkaline earth metal phosphate, an alkaline earth metal aluminate, an alkaline earth metal borate or an alkaline earth metal germinate may be added to the phosphor. A red phosphor such as a lanthanum oxysulfide phosphor activated by Europium (Eu) and Samarium (Sm) also may be added.

One example of a manufacturing process of the blue phosphor 21 is explained.

A compound having SrHPO₄, SrCO₃, SrCl₂, CaCl₂ BaCl₂ and Eu₂O₃ is mixed and calcined in a weak reduction ambient atmosphere and 1000-1200° C. The compound is smashed and meshed. A blue phosphor 21 having a grain size of about 5-10 micrometer is obtained.

The sedimentation speed in the liquid resin depends on such factors as the grain size and relative density. The sedimentation speed is approximated by the Stokes' law and is proportionate to the square of the grain diameter multiplying relative density. A relative density of a blue phosphor 21 having a grain size of about 5-10 micrometers is about 4.2. A relative density of a yellow phosphor 22 having a grain size of about 20-50 micrometers is about 4.6. In this case, since the sedimentation speed of the yellow phosphor 22 is greater than that of the blue phosphor 21, the yellow phosphor 22 is apt to be provided in the bottom side of the resin. When the resin is cured in this state, many of the yellow phosphors 22 are dispersed near the LED chip 100. As a result, a relatively large portion of ultraviolet light may be absorbed by the yellow phosphors 22, in which case the color tone of the light emitted from the device may be yellow emphasized (yellowish) light.

A structure of the combined phosphor in accordance with this embodiment is explained hereinafter with reference to FIG. 9. FIG. 9 is a schematic view of a combined phosphor.

A blue phosphor 21 and yellow phosphor 22 is combined with a binder resin 25. The sedimentation speed of the yellow phosphor 22 is reduced as the blue phosphor 21 which has slower sedimentation speed is attached to the yellow phosphor 22 via the binder resin 25. The ratio of the yellow phosphor 22 to the blue phosphor 21 is substantially uniform in the transparent resin 300. As a result, the variation of the color chiromancy is reduced.

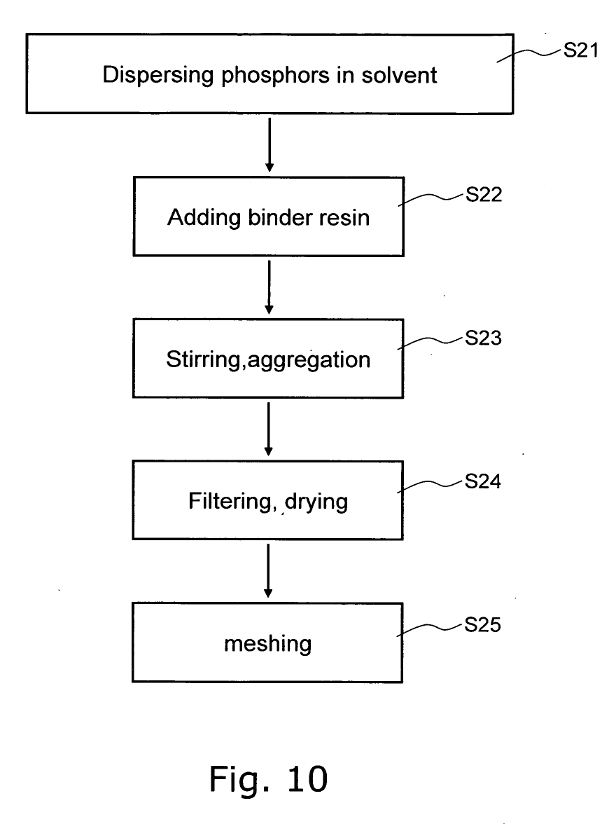

The manufacturing process of the combined phosphor 220 is explained hereinafter with reference to FIG. 10.

FIG. 10 is a flow chart showing a manufacturing process of a combined phosphor.

In Step S21, two kinds of phosphors are dispersed in an organic solvent such as water or alcohol.

In Step S22, a material for binder resin is added in the organic solvent. The material for binder resin may be an acrylic resin or a silicone resin. A concentration of the binder resin may be about 0.01 -0.5%.

In Step S23, the phosphors are aggregated with stirring. For example, the stirring is performed for about one hour. The dispersed phosphors are then aggregated and the phosphors are combined with the binder resin.

In Step S24, the phosphors are filtered and dried.

In Step S25, the phosphors are meshed, such as 200-mesh, and classified.

In this embodiment, white light is obtained by the combined phosphors having the yellow phosphors 22 and the blue phosphors 21. A red phosphor may be added to the combined phosphor 220. Alternatively, a part of the phosphors may not be combined.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

For example, the semiconductor light emitting element is not limited to InGaAlP or GaN structures. Other semiconductor LED are available, such as GaAlP and InP by using a III-V compound semiconductor, II-VI compound semiconductor, and so on. The light emitted from the LED may be visible light instead of ultraviolet light. In addition, the kinds of the phosphor are not limited to one, two or three kinds. Four or more phosphors may be used.

What is claimed is:

1. A semiconductor light emitting device, comprising:
a light emitting element configured to emit a first wavelength light; and
a phosphor configured to absorb the first wavelength light and emit light of a second wavelength which is different from the first wavelength, wherein the phosphor contains a silicate represented by the formula (Me_{1-y}Eu_{y})₂SiO₄, wherein Me is at least one element selected from the group consisting of Ba, Sr, Ca and Mg, and y is >0, and wherein the phosphor has a grain size of from about 10 to about 50 micrometers.

2. A semiconductor light emitting device of claim 1, wherein the phosphor further comprises at least one of an alkaline earth metal phosphate, an alkaline earth metal aluminate, an alkaline earth metal borate, and an alkaline earth metal germinate.

3. A semiconductor light emitting device of claim 1, wherein the grain size of the phosphor is from about 15 to about 50 micrometers.

4. A semiconductor light emitting device of claim 1, wherein the grain size of the phosphor is from about 20 to about 50 micrometers.

5. A semiconductor light emitting device of claim 1 further comprising a resin provided on the light emitting element, wherein the phosphor is dispersed in the resin.

6. A semiconductor light emitting device, comprising:
a light emitting element configured to emit a first wavelength light;
a phosphor configured to absorb the first wavelength light and emit light of a second wavelength which is different from the first wavelength, wherein the phosphor contains a silicate represented by the formula (Me_{1-y}Eu_{y})₂SiO₄, wherein Me is at least one element selected from the group consisting of Ba, Sr, Ca and Mg, and y is >0, and wherein the phosphor has a grain size of from about 10 to about 50 micrometers; and
a particle provided on the phosphor, wherein the particle has a grain size which is less than the grain size of the phosphor.

7. A semiconductor light emitting device of claim 6, wherein the particle is substantially transparent to one of the first wavelength light and the second wavelength light.

8. A semiconductor light emitting device of claim 6, wherein the grain size of the particle is from about 0.01 to about 0.5 micrometers.

9. A semiconductor light emitting device of claim 6, wherein the particle is at least one of a silica, an alumina, an alkaline earth metal hydride, and an alkaline earth metal oxide.

10. A semiconductor light emitting device of claim 6, wherein the phosphor further comprises at least one of an alkaline earth metal phosphate, an alkaline earth metal aluminate, an alkaline earth metal borate, and an alkaline earth metal germinate.

11. A semiconductor light emitting device of claim 6, wherein the grain size of the phosphor is from about 15 to about 50 micrometers.

12. A semiconductor light emitting device of claim 6, wherein the grain size of the phosphor is from about 20 to about 50 micrometers.

13. A semiconductor light emitting device, comprising:
a light emitting element configured to emit a first wavelength light;
a first configured to absorb the first wavelength light and emit light of a second wavelength which is different from the first wavelength, wherein the first phosphor contains a silicate represented by the formula (Me_{1-y}Eu_{y})₂SiO₄, wherein Me is at least one element selected from the group consisting of Ba, Sr, Ca and Mg, and y is >0, and wherein the first phosphor has a grain size of from about 10 to about 50 micrometers; and
a second phosphor configured to absorb the first wavelength light and emit a third wavelength light, wherein the third wavelength light is different in wavelength from the first wavelength light and from the second wavelength light.

14. A semiconductor light emitting device of claim 13, further comprising a binder resin configured to combine the first phosphor and the second phosphor.

15. A semiconductor light emitting device of claim 14, wherein the binder resin is at least one of a silicone resin and an acrylic resin.

16. A semiconductor light emitting device of claim 13, further comprising, a particle provided on one of the first phosphor and the second phosphor, wherein the particle has a grain size which is less than the grain size of at least one of the first phosphor and the second phosphor.

17. A semiconductor light emitting device of claim 16, wherein the particle is substantially transparent to one of the first wavelength light, the second wavelength light and the third wavelength.

18. A semiconductor light emitting device of claim 13, wherein the phosphor further comprises at least one of an alkaline earth metal phosphate, an alkaline earth metal aluminate, an alkaline earth metal borate, and an alkaline earth metal germinate.

19. A semiconductor light emitting device of claim 13, wherein the grain size of the first phosphor is from about 15 to about 50 micrometers.

20. A semiconductor light emitting device of claim 13, wherein the grain size of the first phosphor is from about 20 to about 50 micrometers.
